(19) United States
(12) Patent Application Publication
(10) Pub. No.: US 2007/0298283 A1
(43) Pub. Date: Dec. 27, 2007

(54) Fabrication method and structure of an ITO anode containing nickel for improving injection efficiency of an OLED

(75) Inventors: Ching-Ming Hsu, Tainan County (TW); Wen-Tuan Wu, Tainan County (TW); Hsin-Hui Lee, Tainan County (TW)

Correspondence Address: BACON & THOMAS, PLLC, 625 SLATERS LANE, FOURTH FLOOR, ALEXANDRIA, VA, 22314, US

(73) Assignee: Ching-Ming HSU, Tainan County (TW)

(21) Appl. No.: 11/471,477

(22) Filed: Jun. 21, 2006

(51) Int. Cl. H01L 51/50; H01L 51/56; H05B 33/26; B32B 9/00; C23C 14/00

(52) U.S. Cl. 428/702; 427/126.3; 427/66; 204/192.1; 438/22; 428/690; 428/917; 313/503; 313/506; 257/E51.019

(57) ABSTRACT

A fabrication method of an indium tin oxide (ITO) anode containing nickel for improving injection efficiency of an organic light emitting diode (OLED) includes various processes of preparing an ITO substrate with an anode, of preparing a target source of ITO containing nickel, and of mingling nickel on the anode of the ITO substrate by sputtering. The structure of the ITO anode containing nickel for an OLED includes a substrate with an anode mingled with nickel, a hole transport layer and an electron transport layer. Such an ITO anode is to have a higher work function that can lessen a great potential barrier between the ITO anode and a hole transport layer. So the threshold voltage and the turn-on voltage of OLED can be reduced to advance hole injection efficiency.

### BACKGROUND OF THE INVENTION

1. Field of the Invention

This invention relates to a fabrication method and a structure of an indium tin oxide (ITO) anode containing nickel for improving injection efficiency of an organic light emitting diode (OLED).

2. Description of the Prior Art

As known universally, a conventional OLED (organic light emitting diode) has a structure and a manufacturing procedure simpler than those of LCD nowadays. Moreover, an OLED can light itself and be combined with a flexible substrate, and has no limitation of viewing angles, low power consumption, high brightness and a short response time. Therefore, OLED is potentially applicable to all kinds of audio and video displayers, such as mobile audio, cell phone, MP3, digital camera, PDA, electronic book, back light source of LCD, television and source of white light etc.

FIG. 1 is a diagram of a conventional multi-layer OLED device, which is provided with an ITO (indium tin oxide) substrate 2 possessing an anode 4 that is mostly a transparent conductive electrode, and a hole transport layer (HTL) 6, a light emitting layer (LEL) 8 and an electron transport layer (ETL) 10 located orderly on the anode 4. Finally, a metallic cathode 12 is fabricated on the ETL 10 by vacuum vapor deposition to complete such a conventional multi-layer OLED.

When a positive bias is applied to the OLED, an electric field is to be formed in the OLED. By the time, the electron and the hole are respectively injected to the metallic cathode 12 and anode 4. The electron is to pass through the ETL 10 and the hole is to pass through HTL 6 after the electron and the hole have surpassed the energy barrier of the cathode interface and the anode interface respectively. Then, the electron and the hole meet at the LEL 8 to form a neutralized but excited electron-hole pair, which is to release photon energy by radiation and then, return to the fundamental state. What is mentioned above is a process of electro-luminescence.

As a related conventional skill of OLED, U.S. Pat. No. 6,420,031 B1, titled as “Highly transparent on-metallic cathode”, employs an ITO as a non-metallic layer and copper phthalocyanine (CuPc) as an electron-injecting interface layer. The electron interface with low resistance is formed only when the ITO is set in an organic layer but not when the organic layer is set on the ITO. The CuPc has advantages that: (1) it is used as a protection layer to keep an underlying organic layer from being damaged during the ITO sputtering process; and (2) it is used as an electron-injecting region so as to combine with the ITO layer to transport electron to a neighboring electron transporting layer. But, a highly transparent cathode applied to the OLED in the patent is insufficient to transport because it injects electron to the electron transporting layer without optimization and the materials used are not proper to present the whole range of colors.

As mentioned previously, an electric field is to be formed in the OLED when a positive bias is applied to the OLED. By the time, the electron and the hole are respectively injected to the cathode and the anode. And, the key factor obtaining high injection efficiency is that the electron and the hole must surpass the energy barrier of the cathode interface and the anode interface respectively.

### SUMMARY OF THE INVENTION

The first objective of this invention is to offer a fabrication method of an ITO anode containing nickel for improving injection efficiency of an OLED. The method includes various processes, which are to prepare an ITO substrate with an anode on its surface and to prepare a target source of ITO containing nickel, and to deposit it on the anode of the ITO by sputtering.

The second objective of this invention is to offer a structure of an ITO anode containing nickel for improving injection efficiency of an OLED, at least including a substrate having an anode mingled with nickel, a hole transport layer formed on the anode and an electron transport layer formed on the hole transport layer.

According to the invention, the single target source of ITO containing nickel may contain nickel with 1%, 3% or 5% by weight ratio to ITO.

And, in accordance with what is mentioned above, the potential barrier between the ITO anode and the hole transport layer can be decreased so as to advance the injection efficiency of an OLED.

### BRIEF DESCRIPTION OF DRAWINGS

This invention is better understood by referring to the accompanying drawings, wherein:

FIG. 1 is an illustrating perspective view of a conventional multi-layer OLED device; and

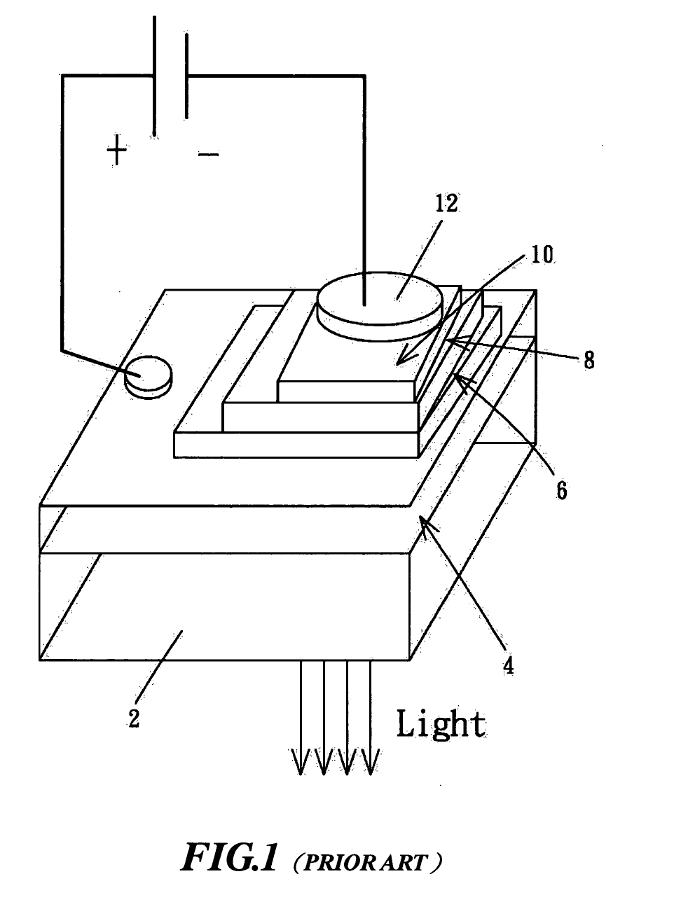

FIG. 2 is a flow chart of a preferred embodiment of a fabrication method of an indium tin oxide (ITO) anode containing nickel for improving injection efficiency of an organic light emitting diode (OLED) in the present invention.

### DETAILED DESCRIPTION OF THE PREFERRED EMBODIMENT

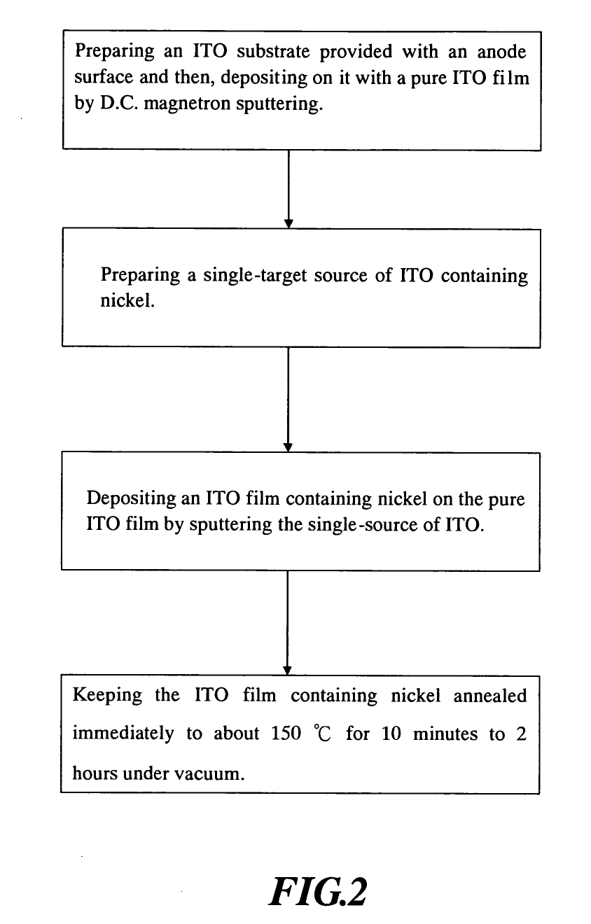

A preferred embodiment of a fabrication method of an indium tin oxide (ITO) anode containing nickel for improving injection efficiency of an organic light emitting diode (OLED) is shown in FIG. 2, a flow chart.

The method includes various processes. A first process is to prepare an ITO substrate with an anode, and a second process is to deposit an ITO film on the anode via direct current magnetron sputtering. Next, a third process is to prepare a single-target source of ITO containing nickel, and a fourth process is to sputter the single-source of the ITO containing nickel on the ITO film originally not mingled with nickel, forming an ITO film mingled with nickel. The temperature of the ITO substrate is controlled between 25-200° C. during sputtering process and the ITO film is successively annealed to about 150° C. for 10 minutes to 2 hours under vacuum.

Moreover, the nickel contained in the single-target source of the ITO film has 1%, 3%, or 5% by weight ratio to the ITO.

Of course, an ITO film mingled with nickel and formed by the process mentioned above should further include at least a hole transport layer formed on the anode of the substrate and an electron transport layer formed on the hole transport layer if applied for an OLED.

It has been proved experimentally that the work function of the anode of the ITO film containing nickel is higher than that of a pure ITO film (approx. 4.6 eV). In addition, different work functions have been achieved when different conditions, such as sputtering power of nickel, have been tested in this invention. So far, the work function of the anode of the ITO film containing nickel is as high as 5.8 eV, able to tremendously lessen a potential barrier between the anode of the ITO and the hole transport layer, reducing about 1.8V of threshold voltage and turn-on voltage of an OLED device, advancing a hole injection efficiency.

As described above, when the invention is applied to a low-voltage driving OLED, it can increase lighting efficiency about 30% because of a highest recombination efficiency of the hole and the electron. Furthermore, the roughness of the ITO anode is improved owing to the employment of nickel, able to effectively reduce productivity of black pixel after the OLED is driven, relatively lengthening the life of the OLED.

The substrate mentioned previously can be replaced with glass, plastics and the like, as long as able to obtain the same or similar effects.

Next, the structure of an ITO anode for an OLED includes an ITO substrate provided with an anode mingled with nickel, a hole transport layer formed on the anode of the ITO substrate, and an electron transport layer formed in the hole transport layer.

While the preferred embodiment of the invention has been described above, it will be recognized and understood that various modifications may be made therein and the appended claims are intended to cover all such modifications that may fall within the spirit and scope of the invention.

What is claimed is:

1. A method of fabricating an indium tin oxide (ITO) anode containing nickel for improving injection efficiency of an organic light emitting diode (OLED), said method comprising:
a first process of preparing an ITO substrate provided with an anode;
a second process of preparing a target source of an ITO mingled with nickel; and,
a third process of sputtering said ITO mingled with nickel on said anode of said ITO substrate.

2. A method of fabricating an indium tin oxide (ITO) anode containing nickel for improving injection efficiency of an organic light emitting diode (OLED) as claimed in claim 1, wherein said ITO substrate is first deposited with a pure ITO film not mingled with nickel by direct current magnetron sputtering.

3. A method of fabricating an indium tin oxide (ITO) anode containing nickel for improving injection efficiency of an organic light emitting diode (OLED) as claimed in claim 1, wherein the temperature of said ITO substrate is controlled between 25-200° C. during said direct magnetron sputtering process.

4. A method of fabricating an indium tin oxide (ITO) anode containing nickel for improving injection efficiency of an organic light emitting diode (OLED) as claimed in claim 1, wherein said ITO film finishing said third process is successively annealed to about 150° C. under vacuum.

5. A structure of an indium tin oxide (ITO) anode containing nickel for improving injection efficiency of an organic light emitting diode (OLED), said structure at least comprising:
a substrate provided with an anode mingled with nickel;
a hole transport layer formed on said anode of said substrate; and
an electron transport layer formed on said hole transport layer.

6. A structure of an indium tin oxide (ITO) anode containing nickel for improving injection efficiency of an organic light emitting diode (OLED) as claimed in claim 5, wherein said substrate is glass.

7. A structure of an indium tin oxide (ITO) anode containing nickel for improving injection efficiency of an organic light emitting diode (OLED) as claimed in claim 5, wherein said substrate is plastics.
